(19) United States
(12) Patent Application Publication
(10) Pub. No.: US 2026/0334042 A1
(43) Pub. Date: Oct. 22, 2026

(54) ELECTRONIC DEVICE AND DISPLAY PANEL INCLUDED THEREIN

(71) Applicant: Samsung Display Co., Ltd., Yongin-si (KR)

(72) Inventors: JUNSEOK MIN, Yongin-si (KR); WONKYU KWAK, Yongin-si (KR); DONGJIN MOON, Yongin-si (KR); HYEYUN HAN, Yongin-si (KR)

(21) Appl. No.: 19/529,524

(22) Filed: Feb. 4, 2026

(30) Foreign Application Priority Data
Apr. 16, 2025 (KR) 10-2025-0049210

(51) Int. Cl. H10K 59/40; H10K 59/131; H10K 59/80

(52) U.S. Cl. CPC H10K 59/40; H10K 59/131; H10K 59/8792

(57) ABSTRACT

An electronic device includes an electronic module, and an electronic panel including a first region including a transmissive region and an element region above the electronic module, a second region adjacent the first region, a substrate, a circuit element layer above the substrate and including signal lines including an inner signal section in the transmissive region, and pixel circuits, a display element layer including light-emitting elements connected to the pixel circuits, the light-emitting elements including a pixel electrode, a light-emitting layer above the pixel electrode, and a common electrode above the light-emitting layer and defining electrode openings overlapping the transmissive region, and a sensor layer above the display element layer and including conductive patterns including sensing patterns overlapping the common electrode, and a dummy pattern overlapping the common electrode, between the inner signal section and the sensing patterns in a plan view, and not electrically connected to the sensing patterns.

### CROSS-REFERENCE TO RELATED APPLICATION

The present application claims priority to, and the benefit of, Korean Patent Application No. 10-2025-0049210, filed on Apr. 16, 2025, in the Korean Intellectual Property Office, the entire disclosure of which is incorporated herein by reference.

### BACKGROUND

The present disclosure herein relates to an electronic device having enhanced transmittance in a corresponding region, and exhibiting improved sensing sensitivity, and a display panel in the electronic device.

Electronic devices may be devices that include various electronic components, such as display panels and electronic modules. Such an electronic module may include a camera, an infrared detection sensor, a proximity sensor, etc. The electronic module may be located below a display panel. The transmittance in some regions of the display panel may be higher than the transmittance in other regions of the display panel. The electronic module may receive an external input via some regions of the display panel or provide an output via some regions of the display panel.

The electronic device may include an input-sensing unit for receiving the external input. The input-sensing unit is located on the display panel, and senses a touch of a user as an external input. The input-sensing unit includes a plurality of sensing units that form capacitance to sense the external input.

### SUMMARY

The present disclosure provides an electronic device that has enhanced transmittance in a corresponding region, and that exhibits improved sensing sensitivity by reducing or preventing noise from being generated in a sensing electrode.

The present disclosure also provides a display panel that provides high-quality images, and that exhibits improved sensing sensitivity by reducing or preventing noise from being generated in a sensing electrode included in a sensor layer of the display panel.

One or more embodiments provides an electronic device including an electronic module, and an electronic panel including a first region including a transmissive region and an element region above the electronic module, a second region adjacent to the first region, a substrate, a circuit element layer above the substrate and including signal lines including an inner signal section in the transmissive region, and pixel circuits, a display element layer including light-emitting elements electrically and respectively connected to the pixel circuits, the light-emitting elements including a pixel electrode, a light-emitting layer above the pixel electrode, and a common electrode above the light-emitting layer and defining electrode openings overlapping the transmissive region in a plan view, and a sensor layer above the display element layer and including conductive patterns including sensing patterns overlapping the common electrode, and a dummy pattern overlapping the common electrode, between the inner signal section and the sensing patterns in a plan view, and not electrically connected to the sensing patterns.

A cut portion may be defined between one of the sensing patterns and the dummy pattern.

The sensing patterns and the dummy pattern may include a mesh line.

The sensing patterns may include a first mesh line, wherein the dummy pattern includes a second mesh line having a width that is less than or equal to a width of the first mesh line.

The circuit element layer may further include a rear metal layer above the substrate and defining a light-blocking opening overlapping the transmissive region in a plan view.

The electrode openings may include a first electrode opening with the inner signal section therein, and a second electrode opening adjacent to each other, wherein the dummy pattern is adjacent to a target-sensing pattern among the sensing patterns that is partially between the first electrode opening and the second electrode opening.

The target-sensing pattern may include a connecting section between the first electrode opening and the second electrode opening.

The inner signal section may be adjacent to a first edge of the first electrode opening in a plan view, wherein the dummy pattern is adjacent to the first edge of the first electrode opening in a plan view, and wherein the first edge of the first electrode opening is between the dummy pattern and the inner signal section in a plan view. The display element layer may further include a pixel-defining layer above the circuit element layer and configured to absorb light.

The electronic panel may further include a thin film encapsulation layer above the display element layer and covering the light-emitting elements, wherein the sensor layer is directly on the thin film encapsulation layer.

The circuit element layer may further include inorganic insulating layers above the substrate, wherein the inner signal section is above one of the inorganic insulating layers.

The circuit element layer may further include organic insulating layers above the inorganic insulating layers.

The sensor layer may include a sensor base layer above the display element layer, a first sensor conductive layer above the sensor base layer, a sensor insulating layer above the first sensor conductive layer, and a second sensor conductive layer above the sensor insulating layer.

The electronic panel may further include an anti-reflection layer above the sensor layer and including a black matrix defining split openings respectively overlapping the light-emitting elements, and color filters respectively corresponding to the split openings.

The black matrix may define a transmissive opening at least partially overlapping the transmissive region, wherein the color filters are spaced from the transmissive opening.

In one or more embodiments, an electronic device includes an electronic module, and an electronic panel including a first region above the electronic panel and including a transmissive region and an element region, a second region adjacent to the first region, a substrate, a circuit element layer above the substrate and including signal lines including an inner signal section in the transmissive region, and pixel circuits above the substrate, a display element layer including light-emitting elements electrically and respectively connected to the pixel circuits and including a pixel electrode, a light-emitting layer above the pixel electrode, and a common electrode above the light-emitting layer and defining electrode openings partially overlapping the transmissive region in a plan view, and a sensor layer above the display element layer and including conductive patterns including a sensing pattern overlapping the common electrode, and a dummy pattern overlapping the common electrode, adjacent to the inner signal section in a plan view, and spaced apart from the sensing pattern with a cut portion therebetween.

The electrode openings may include a first electrode opening in which the inner signal section is located, wherein the inner signal section is adjacent to a first edge of the first electrode opening in a plan view, wherein the dummy pattern is adjacent to the first edge of the first electrode opening in a plan view, and wherein the first edge of the first electrode opening is between the dummy pattern and the inner signal section.

The circuit element layer may further include inorganic insulating layers above the substrate, wherein the inner signal section is above one of the inorganic insulating layers.

The electronic panel may further include an anti-reflection layer above the sensor layer and including a black matrix defining split openings respectively overlapping the light-emitting elements and a transmissive opening at least partially overlapping the transmissive region, and color filters respectively corresponding to the split openings and spaced from the transmissive opening.

In one or more embodiments, a display panel includes a first region including a transmissive region and an element region, a second region adjacent to the first region, a substrate, a circuit element layer above the substrate and including signal lines including an inner signal section in the transmissive region, and pixel circuits, a display element layer including light-emitting elements respectively electrically connected to the pixel circuits and including a pixel electrode, a light-emitting layer above the pixel electrode, and a common electrode above the light-emitting layer and defining electrode openings partially overlapping the transmissive region in a plan view, and a sensor layer above the display element layer and including conductive patterns including sensing patterns overlapping the common electrode, and a dummy pattern overlapping the common electrode, between the inner signal section and the sensing patterns in a plan view, and not electrically connected to the sensing patterns.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain aspects of the present disclosure. In the drawings:

FIG. 1 is a block diagram of an electronic device according to one or more embodiments;

FIG. 2 shows schematic views of embodiments of various electronic devices;

FIG. 3 is a perspective view of an electronic device according to one or more embodiments of the present disclosure;

FIG. 4 is an exploded perspective view of an electronic device according to one or more embodiments of the present disclosure;

FIG. 5 is a diagram illustrating an example of the cross-section of the electronic device shown in FIG. 3;

FIG. 6 is a diagram illustrating an example of the cross-section of the display layer shown in FIG. 5;

FIG. 7 is a plan view of a display panel according to one or more embodiments of the present disclosure;

FIG. 8 is a plan view of a sensor layer according to one or more embodiments of the present disclosure;

FIGS. 9A and 9B are plan views each showing a portion of a display panel according to one or more embodiments;

FIG. 10 is a cross-sectional view of a display module according to one or more embodiments of the present disclosure;

FIGS. 11A and 11B are plan views each showing a portion of a display module according to one or more embodiments; and

FIG. 12 is a cross-sectional view of a display module according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

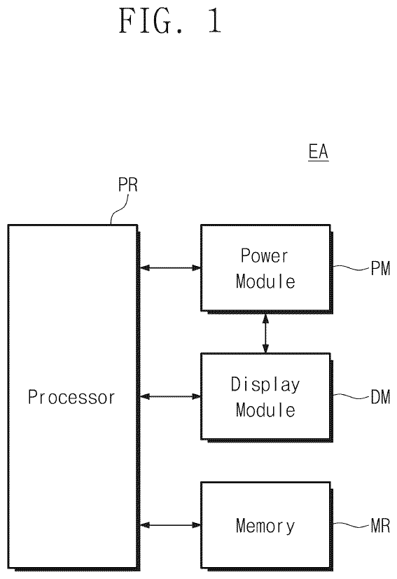

FIG. 1 is a block diagram of an electronic device according to one or more embodiments.

Referring to FIG. 1, an electronic device EA according to one or more embodiments may include a display module DM, a processor PR, a memory MR, and a power module PM.

The processor PR may include at least one of a central processing unit (CPU), an application processor (AP), a graphic processing unit (GPU), a communication processor (CP), an image signal processor (ISP), or a controller.

The memory MR may store data information that is required for an operation of the processor PR or the display module DM. When the processor PR executes an application stored in the memory MR, image data signals and/or input control signals may be transmitted to the display module DM, and the display module DM may process the received signals and output image information via a display screen. The display module DM may include a display panel for displaying images.

The power module PM may include a power conversion module. The power conversion module may convert power supplied by a power supply module, such as a power adapter and a battery device, and may generate power required for operations of the electronic device EA.

At least one component in the electronic device EA described above may be included in a display module and a display device including the display module according to embodiments described below. In addition, some of individual modules functionally included in a single module may be provided inside the display device, while others may be provided separately from the display device. For example, the display device may include the display module DM, and the processor PR, the memory MR, and the power module PM may be provided in the form of other devices inside the electronic device EA, which are different from the display device.

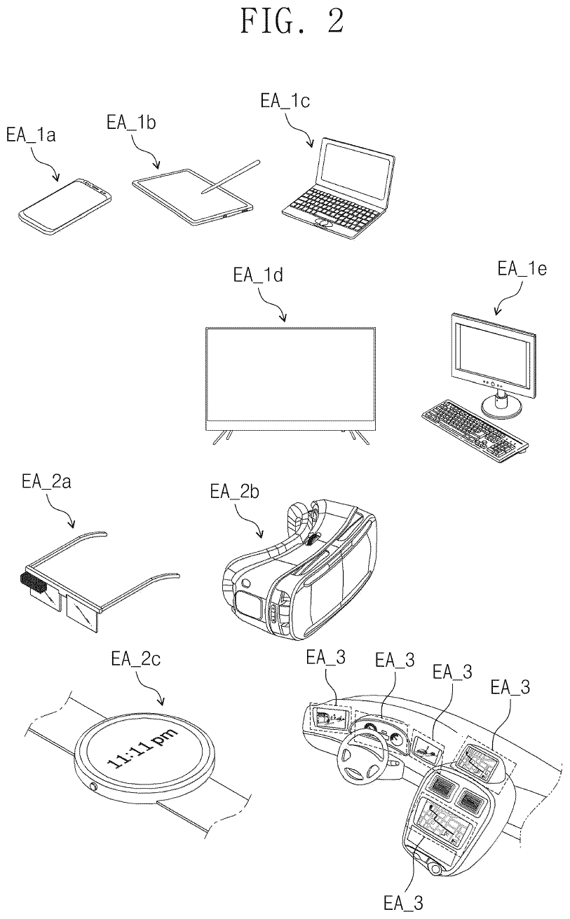

FIG. 2 shows schematic views of embodiments of various electronic devices.

Referring to FIG. 2, various electronic devices including display modules according to one or more embodiments may include image display electronic devices, such as a smartphone EA_1a, a tablet personal computer (PC) EA_1b, a laptop EA_1c, a television (TV) EA_1d, and a desktop monitor EA_1e. In addition, the electronic devices may include wearable electronic devices, such as smart glasses EA_2a, a head-mounted display EA_2b, and a smart watch EA_2c. Furthermore, the electronic devices may include vehicle electronic devices EA_3, such as a room mirror display and a center information display (CID) placed on an instrument panel, a center fascia, or a dashboard of a vehicle.

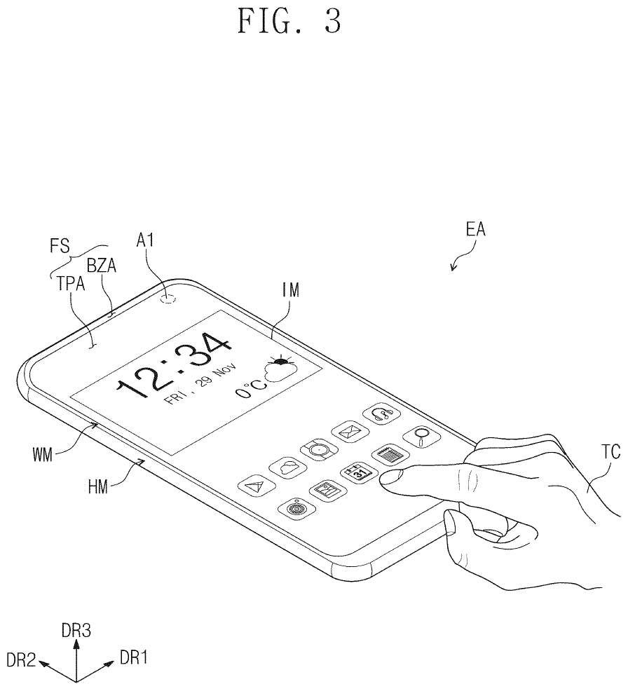

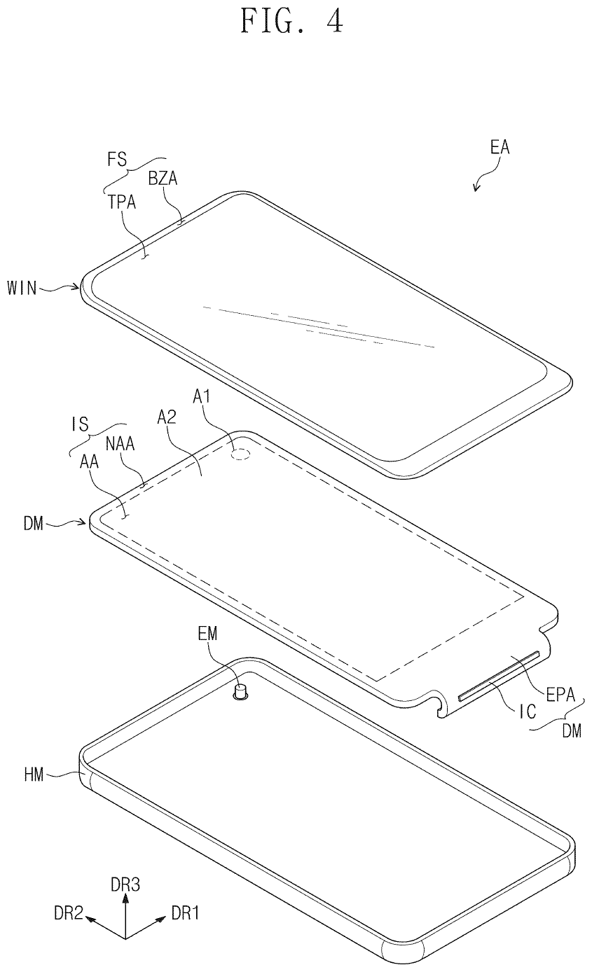

FIG. 3 is a perspective view of an electronic device according to one or more embodiments of the present disclosure. FIG. 4 is an exploded perspective view of an electronic device according to one or more embodiments of the present disclosure.

In one or more embodiments, the electronic device EA is illustrated as a smartphone.

The electronic device EA may display an image IM, in a third direction DR3, via a display surface FS that is parallel to each of a first direction DR1 and a second direction DR2. The display surface FS, on which the image IM is displayed, may correspond to a front surface of the electronic device EA and may also correspond to a front surface FS of a window module WM. Hereinafter, the display surface and front surface of the electronic device EA and the front surface of the window module WM are designated by the same reference symbol. The image IM may include static images as well as dynamic images. In FIG. 3, a watch and a plurality of icons are illustrated as examples of the image IM.

In one or more embodiments, the front surface (or the front surface) and the rear surface (or the lower surface) of each member are defined based on the direction in which the image IM is displayed. The front surface and the rear surface are opposite to each other in the third direction DR3, and the normal direction of each of the front surface and the rear surface may be parallel to the third direction DR3. The distance between the front surface and the rear surface in the third direction DR3 may correspond to the thickness of an electronic device EA in the third direction DR3. The directions indicated by the first to third directions DR1, DR2, and DR3 are relative concepts and may be changed to other directions. Hereinafter, the first to third directions refer to the same reference symbols as the directions indicated by the first to third directions DR1, DR3, and D3, respectively.

The electronic device EA according to one or more embodiments of the present disclosure may sense a user input TC applied from outside. The user input TC includes various types of external inputs, such as parts of the user's body, light, heat, and pressure. In one or more embodiments, the user input TC is shown as the user's hand applied to the front surface. However, this is only an example, and as described above, the user input TC may be provided in various forms. In addition, the electronic device EA may sense the user input TC applied to the side surface or rear surface of the electronic device EA depending on the structure of the electronic device EA, and this is not limited to any one embodiment.

In one or more embodiments, a first region A1 may be defined overlapping a transparent region TPA. The first region A1 may be a region defined in the display module DM described below, and may be a region overlapping the display module DM in a plan view. The electronic device EA may receive, via the first region A1, an external signal required by an electronic module EM, or may provide, to the outside, a signal output from the electronic module EM. According to the present disclosure, as the first region A1 overlaps the transparent region TPA, the area of a bezel region BZA may be reduced.

Referring to FIG. 4, the electronic device EA includes a window module WM, a housing unit HM, a display module DM, and an electronic module EM. In one or more embodiments, the window module WM and the housing unit HM may be coupled together to form the exterior of the electronic device EA.

The window module WM may include an insulating panel. For example, the window module WM may include glass, plastic, or a combination thereof. As described above, the front surface FS of the window module WM may define the front surface of the electronic device EA. The transparent region TPA may be optically transparent. For example, the transparent region TPA may be a region having a visible light transmittance of about 90% or more.

The bezel region BZA may have relatively lower light transmittance than the transparent region TPA. The bezel region BZA may define the shape of the transparent region TPA. The bezel region BZA may be adjacent to the transparent region TPA and surround the transparent region TPA. The bezel region BZA may have a corresponding color. The bezel region BZA may be defined by a bezel layer that is provided separately from a transparent substrate defining the transparent region TPA, or may be defined by an ink layer that is inserted into or colored on the transparent substrate. The bezel region BZA may cover a peripheral region NAA of the display module DM and reduce or prevent visibility of the peripheral region NAA from the outside. This is only an example, and in the window module WM according to one or more embodiments of the present disclosure, the bezel region BZA may be omitted.

The display module DM may include an electronic panel EPA and a drive circuit IC. The electronic panel EPA may display the image IM and sense the external input TC. A front surface IS of the electronic panel EPA may include an active region AA (or a display region) and a peripheral region NAA (or a non-display region). The active region AA may be activated in response to an electrical signal.

In one or more embodiments, the active region AA may be a region on which an image IM is displayed and, at the same time, a region on which the external input TC is sensed. The active region AA may be a region in which a plurality of light-emitting elements described below are arranged.

At least a portion of the transparent region TPA may overlap the active region AA. For example, the transparent region TPA may completely or at least partially overlap the active region AA. Accordingly, a user may identify the image IM or provide the external input TC, via the transparent region TPA. However, this is only an example. In the active region AA, a region on which the image IM is displayed and a region on which the external input TC is sensed may be separated from each other, and the present disclosure is not limited to any one embodiment.

The peripheral region NAA may be covered by the bezel region BZA. The peripheral region NAA may be adjacent to the active region AA. The peripheral region NAA may surround the active region AA. The peripheral region NAA may be a region from which the image IM is not displayed. In the peripheral region NAA, a drive circuit or a drive line for driving the active region AA may be provided.

In one or more embodiments, a portion of the peripheral region NAA of the electronic panel EPA may be bent. For example, a portion of the peripheral region NAA may face the rear surface of the electronic device EA, and thus, the bezel region BZA visible on the front surface of the electronic device EA may be reduced. Also, the electronic panel EPA may be assembled in a state in which a portion of the active region AA is bent. However, this is only an example. In one or more embodiments, the electronic panel EPA may be assembled in a state in which the active region AA and the peripheral region NAA face the window module WM while maintaining a flat state. In addition, in the electronic panel EPA according to one or more embodiments of the present disclosure, the peripheral region NAA may be omitted.

The active region AA (or the display region) may include a first region A1 and a second region A2. The first region A1 may be defined in a region overlapping the electronic module EM in a plan view. In one or more embodiments, the first region A1 is shown as a circular shape, but may have various shapes, such as a polygon, an ellipse, and a shape having at least one curved side, and the present disclosure is not limited to any one embodiment.

The second region A2 may be adjacent to the first region A1. The second region A2 may be a region having relatively lower transmittance than the first region A1. In one or more embodiments, the second region A2 is shown as completely surrounding the edge of the first region A1. However, this is only an example. The second region A2 may be defined as being adjacent only to a portion of the edge of the first region A1, and the present disclosure is not limited to any one embodiment.

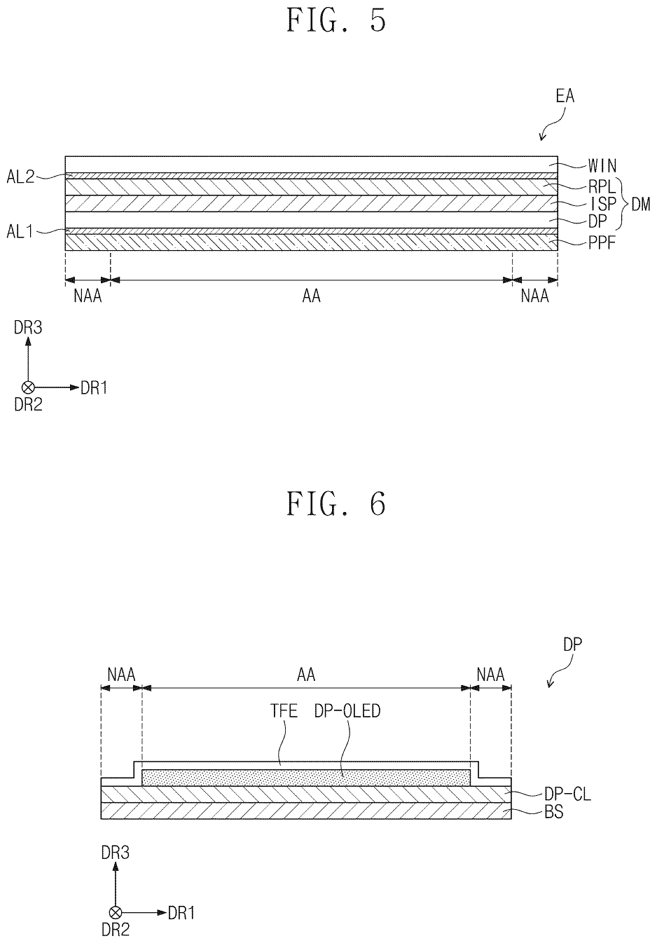

FIG. 5 is a diagram illustrating an example of the cross-section of the electronic device shown in FIG. 3. FIG. 6 is a diagram illustrating an example of the cross-section of the display layer shown in FIG. 5.

Referring to FIG. 5, the electronic device EA may include a display panel DP, a sensor layer ISP, an anti-reflection layer RPL, a window WIN, a panel protective film PPF, and first and second adhesive layers AL1 and AL2.

The display panel DP according to one or more embodiments of the present disclosure may be a light-emitting display panel. For example, the display panel DP may be an organic light-emitting display panel or an inorganic light-emitting display panel. A light-emitting layer of the organic light-emitting display panel may include an organic light-emitting material. A light-emitting layer of the inorganic light-emitting display panel may include quantum dots or quantum rods. Hereinafter, the display panel DP is described as an example of the organic light-emitting display panel.

Referring to FIG. 6, the display panel DP may include a substrate BS, a circuit element layer DP-CL, a display element layer DP-OLED, and a thin film encapsulation layer TFE. The circuit element layer DP-CL, the display element layer DP-OLED, and the thin film encapsulation layer TFE may be located in this order on the substrate BS.

The substrate BS may include glass or a thermoplastic material, such as polyimide (PI).

A plurality of pixels may be arranged on the circuit element layer DP-CL and the display element layer DP-OLED. Each of the pixels may include a transistor located in the circuit element layer DP-CL and a light-emitting element located in the display element layer DP-OLED and connected to the transistor.

The thin film encapsulation layer TFE may be located on the circuit element layer DP-CL to cover the display element layer DP-OLED. The thin film encapsulation layer TFE may protect the pixels from moisture, oxygen, and foreign materials from outside. In one or more embodiments, the thin film encapsulation layer TFE is shown as completely covering the substrate BS. However, in one or more embodiments of the present disclosure, the substrate BS may include a region exposed from the thin film encapsulation layer TFE. Also, the region exposed from the thin film encapsulation layer TFE may be formed along the edge of the substrate BS, and the present disclosure is not limited to any one embodiment.

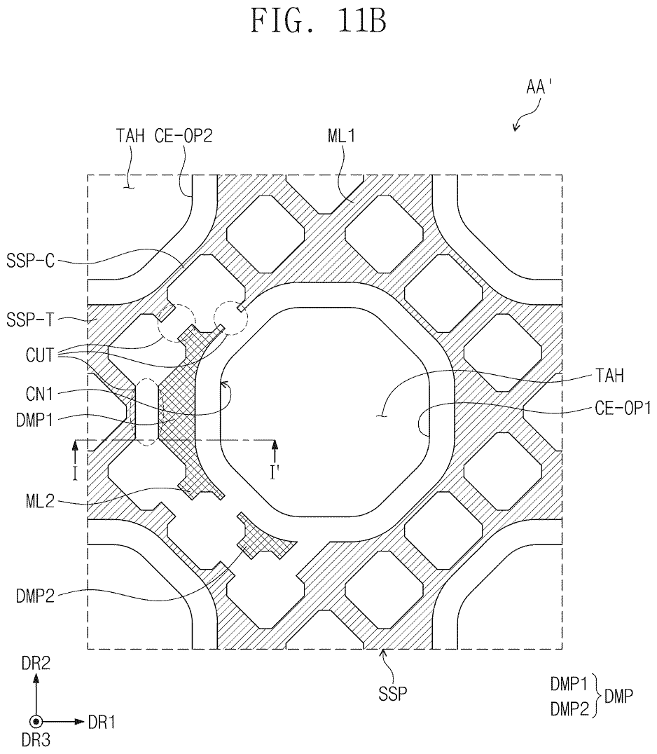

Referring to FIG. 5, the sensor layer ISP may be located on the display panel DP. The sensor layer ISP may include a plurality of sensing patterns SSP (FIG. 11B) for sensing an external input by a capacitance method. The sensor layer ISP may be formed directly on the display panel DP during the manufacturing of the electronic device EA. For example, a conductive pattern or an insulating layer constituting the sensor layer ISP may be directly deposited on or patterned in the display panel DP. However, the present disclosure is not limited thereto, and the sensor layer ISP may be manufactured as a panel separate from the display panel DP and attached to the display panel DP by an adhesive layer.

Referring to FIG. 5, the anti-reflection layer RPL may be located on the sensor layer ISP. The anti-reflection layer RPL may reduce the reflectance of external light in the electronic device EA, thereby improving the visibility of images displayed on the electronic device EA. The anti-reflection layer RPL may include a phase retarder, a polarizer, a black matrix, a color filter, etc., and the present disclosure is not limited to any one embodiment. The anti-reflection layer RPL may be formed directly on the sensor layer ISP by a coating or deposition process, or may be provided in the form of a film and attached to the sensor layer ISP via an adhesive layer, and the present disclosure is not limited to any one embodiment.

The window WIN may be located on the anti-reflection layer RPL. The window WIN may protect the display panel DP, the sensor layer ISP, and the anti-reflection layer RPL against scratches and impacts from outside. The window WIN may correspond to the window module WM described with reference to FIGS. 3 and 4.

The panel protective film PPF may be located below the display panel DP. The panel protective film PPF may support the display panel DP and protect a lower portion of the display panel DP. The panel protective film PPF may have insulating characteristics. For example, the panel protective film PPF may include resin, such as polyethyleneterephthalate (PET), polyimide (PI), and polypropylene (PP), but the present disclosure is not limited thereto.

The first adhesive layer AL1 may be located between the display panel DP and the panel protective film PPF, and the display panel DP and the panel protective film PPF may be bonded to each other by the first adhesive layer AL1. The second adhesive layer AL2 may be located between the window WIN and the anti-reflection layer RPL, and the window WIN and the anti-reflection layer RPL may be bonded to each other by the second adhesive layer AL2.

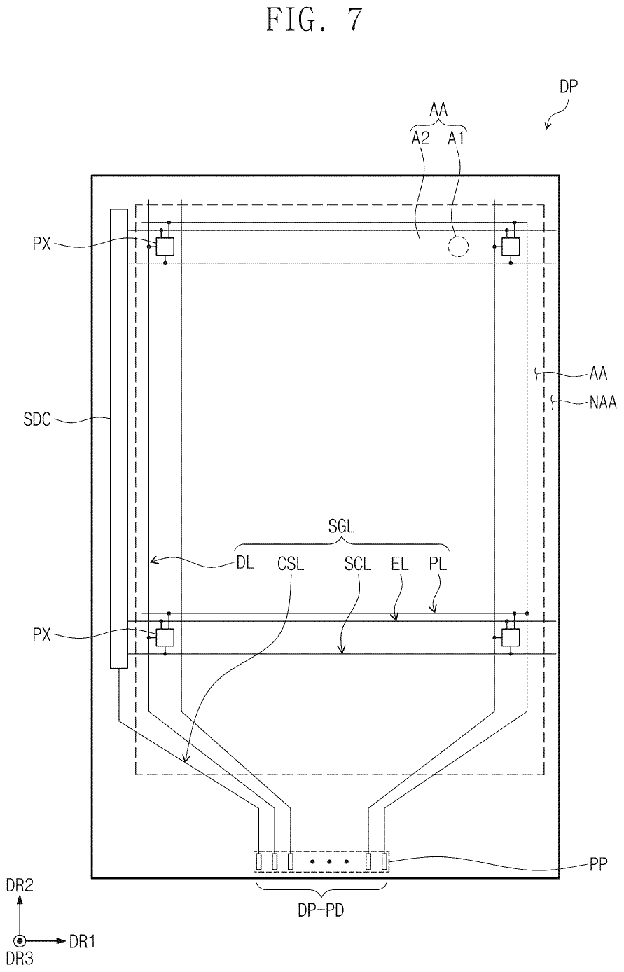

FIG. 7 is a plan view of a display panel according to one or more embodiments of the present disclosure.

Referring to FIG. 7, in the display panel DP, a display region AA, and a non-display region NAA around the display region AA, may be defined. The display region AA and the non-display region NAA may be distinguished from each other on the basis of the presence or absence of a pixel PX. The pixel PX may be provided in the display region AA. The pixel PX may not be located in the non-display region NAA.

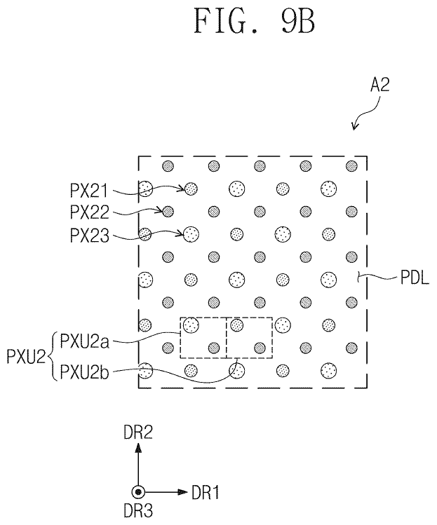

The display region AA may include a first region A1 and a second region A2. The first region A1 and the second region A2 may be distinguished from each other on the basis of the arrangement intervals between pixels PX, the shapes of pixels PX, or the presence or absence of a transmissive portion TAH (see FIG. 9). This is described in detail below.

The display panel DP may include a scan drive circuit SDC, a plurality of signal lines SGL (hereinafter referred to as signal lines), a plurality of signal pads DP-PD, and a plurality of pixels PX.

The scan drive circuit SDC may generate a plurality of scan signals (hereinafter referred to as scan signals), and may sequentially output the scan signals to a plurality of scan lines SCL (hereinafter referred to as scan lines) described below. The scan drive circuit SDC may output not only the scan signals but also other control signals to the pixels PX. The scan drive circuit SDC may include a plurality of transistors that are formed by the same process as the transistors in the pixels PX.

The signal lines SGL may include scan lines SCL, data lines DL, a power line PL, light-emitting control lines EL, and a control signal line CSL. Each of the scan lines SCL, the data lines DL, and the light-emitting control lines EL may be connected to a corresponding pixel PX among the pixels PX. The power line PL may be shared by the pixels PX. The control signal line CSL may provide control signals to the scan drive circuit SDC. The power supply line PL may provide the voltage required for operations of pixels PX. The power supply line PL may include a plurality of lines that provide different voltages.

The signal pads DP-PD may be electrically connected to the data lines DL, the power line PL, and the control signal line CSL. The signal pads DP-PD may be arranged adjacent to each other in a pad region PP that is defined in a portion of the peripheral region NAA.

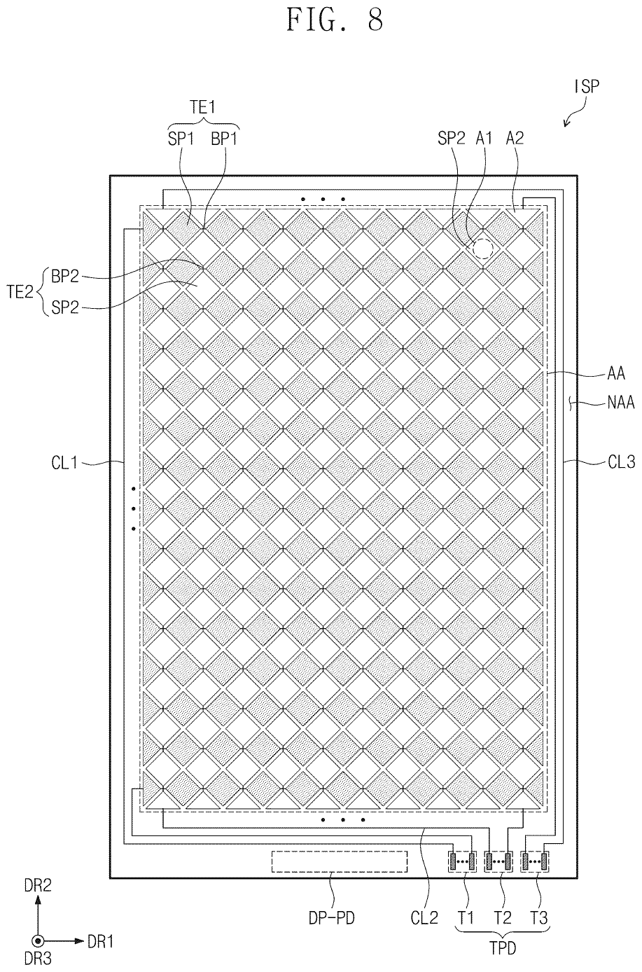

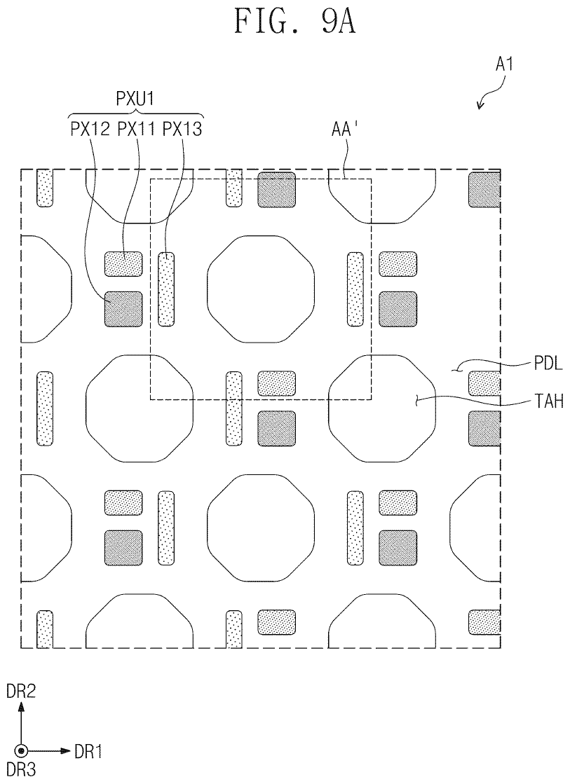

FIG. 8 is a plan view of a sensor layer according to one or more embodiments of the present disclosure.

The sensor layer ISP may be located on the display panel DP (see FIG. 5). The sensor layer ISP may sense the external input TC (see FIG. 3), and may obtain the information about the position or intensity of the external input TC. The sensor layer ISP may include a plurality of first sensing electrodes TE1 (or first sensing electrodes), a plurality of first connection patterns BP1, a plurality of second sensing electrodes TE2 (or second electrodes), a plurality of second connection patterns BP2, a plurality of sensing lines CL1, CL2, and CL3, and a plurality of sensing pads TPD.

The first sensing electrodes TE1 and the second sensing electrodes TE2 may be arranged in the active region AA (or the display region). The sensor layer ISP may obtain information about the external input TC by detecting changes in the capacitance between the first sensing electrodes TE1 and the second sensing electrodes TE2.

The first sensing electrodes TE1 may each extend in the first direction DR1, and may be arranged in the second direction DR2. Each of the first sensing electrodes TE1 may include a first sensing pattern SP1 and a first connection pattern BP1.

The first sensing pattern SP1 may be located in the display region AA. In one or more embodiments, the first sensing pattern SP1 may have a rhombus shape. However, this is only an example. The first sensing pattern SP1 may have various shapes, and the present disclosure is not limited to any one embodiment.

In one or more embodiments, the first connection patterns BP1 may extend in the first direction DR1. Each of the first connection patterns BP1 may be connected to the first sensing pattern SP1. One first connection pattern BP1 may be located between two first sensing patterns SP1 and connect the two first sensing patterns SP1 to each other.

The second sensing electrodes TE2 may each extend in the second direction DR2, and may be arranged in the first direction DR1. Each of the second sensing electrodes TE2 may include a second sensing pattern SP2 and a second connection pattern BP2.

The second sensing pattern SP2 may be located in the display region AA. In one or more embodiments, the second sensing pattern SP2 may have the same shape as the first sensing pattern SP1. For example, the second sensing pattern SP2 may have a rhombus shape. However, this is only an example. The second sensing pattern SP2 may have various shapes, and the present disclosure is not limited to any one embodiment.

In one or more embodiments, the second connection patterns BP2 may extend in the second direction DR2. The second connection pattern BP2 may be connected to the second sensing pattern SP2. The second connection pattern BP2 may be located between two second sensing patterns SP2, and may connect the two second sensing patterns SP2 to each other.

The sensing lines CL1, CL2, and CL3 may be arranged in the peripheral region NAA. The sensing lines CL1, CL2, and CL3 may include first sensing lines CL1, second sensing lines CL2, and third sensing lines CL3. The first sensing lines CL1 may be respectively connected to the first sensing electrodes TE1. The second sensing lines CL2 may be respectively connected to ends of the second sensing electrodes TE2.

The third sensing lines CL3 may be respectively connected to the other ends of the second sensing electrodes TE2. The ends of the second sensing electrodes TE2 may be opposite to the other ends of the second sensing electrodes TE2. According to the present disclosure, the second sensing electrodes TE2 may be connected to the second sensing lines CL2 and the third sensing lines CL3. Accordingly, it is possible to maintain uniform sensitivity according to regions for the second sensing electrodes TE2 that have relatively greater lengths than the first sensing electrodes TE1. This is only an example, and the third sensing lines CL3 may be omitted. The present disclosure is not limited to any one embodiment.

The sensing pads TPD may be arranged in the peripheral region NAA. The sensing pads TPD may include first sensing pads T1, second sensing pads T2, and third sensing pads T3. The first sensing pads T1 may be respectively connected to the first sensing lines CL1, and may provide an external signal to the first sensing electrodes TE1. The second sensing pads T2 may be respectively connected to the second sensing lines CL2, and the third sensing pads T3 may be respectively connected to the third sensing lines CL3, and thus may be electrically connected to the second sensing electrodes TE2.

FIGS. 9A and 9B are plan views each showing a portion of a display panel according to one or more embodiments. FIG. 9A is a plan view of the first region A1 of the display panel according to one or more embodiments, and FIG. 9B is a plan view of the second region A2 of the display panel according to one or more embodiments.

Referring to FIGS. 7, 9A, and 9B, the display panel DP may include the plurality of pixels PX.

The plurality of pixels PX may include a plurality of first pixels PX11, PX12, and PX13. The plurality of first pixels PX11, PX12, and PX13 may be arranged in the first region A1. The plurality of first pixels PX11, PX12, and PX13 may include a (1-1)-th color pixel PX11, a (1-2)-th color pixel PX12, and a (1-3)-th color pixel PX13. The (1-1)-th color pixel PX11 may be a red light-emitting pixel, the (1-2)-th color pixel PX12 may be a green light-emitting pixel, and the (1-3)-th color pixel PX13 may be a blue light-emitting pixel.

The plurality of first pixels PX11, PX12, and PX13 may define a first pixel unit PXU1. The shape of each of the plurality of first pixels PX11, PX12, and PX13 in a plan view may correspond to the shape of a light-emitting region defined in the light-emitting element. The light-emitting region may be a region defined by a pixel-defining layer PDL.

The first region A1 may have higher light transmittance than the second region A2. The first region A1 may display an image. The pixel density of the first region A1 may be lower than that of the second region A2, or the resolution of the first region A1 may be lower than that of the second region A2. The pixel density or resolution of the first region A1 may be about 30% to about 70% of the pixel density or resolution of the second region A2. For example, the pixel density or resolution of the first region A1 may be about 50% of the pixel density or resolution of the second region A2.

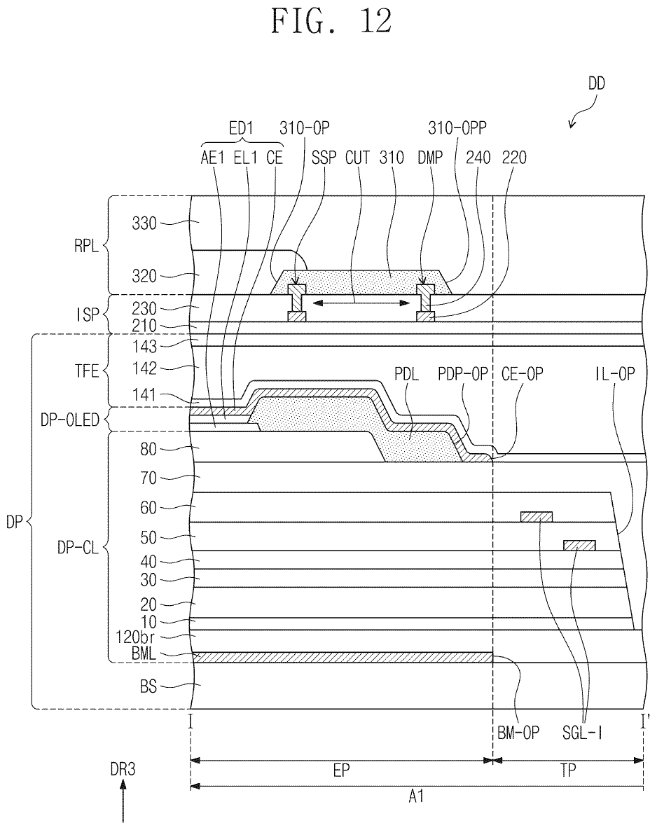

A transmissive portion TAH may be defined in the first region A1. A plurality of transmissive portions TAH may be provided in the first region A1. The transmissive portion TAH may be defined by an electrode opening CE-OP (FIG. 12) described below. The plurality of transmissive portions TAH may be provided in the first region A1, and the pixel density or resolution of the first region A1 may be lower than that of the second region A2.

The shape of each transmissive portion TAH might not be circular. For example, the shape of each of the transmissive portions TAH may be formed as a closed line, and may have irregular shapes including polygons, curves, and straight lines, or irregular shapes including curves with different curvatures. The shape of each of the transmissive portions TAH may have various shapes, and the present disclosure is not limited to any one embodiment.

The plurality of pixels PX may include a plurality of second pixels PX21, PX22, and PX23.

The plurality of second pixels PX21, PX22, and PX23 may be arranged in the second region A2. The plurality of second pixels PX21, PX22, and PX23 may include a (2-1)-th color pixel PX21, a (2-2)-th color pixel PX22, and a (2-3)-th color pixel PX23. The (2-1)-th color pixel PX21 may be a red light-emitting pixel, the (2-2)-th color pixel PX22 may be a green light-emitting pixel, and the (2-3)-th color pixel PX23 may be a blue light-emitting pixel.

The plurality of second pixels PX21, PX22, and PX23 may define a second pixel unit PXU2. The shape of each of the plurality of second pixels PX21, PX22, and PX23 in a plan view may correspond to the shape of a light-emitting region defined in the light-emitting element. The light-emitting region may be a region defined by the pixel-defining layer PDL.

The plurality of second pixels PX21, PX22, and PX23 may define the second pixel unit PXU2. The second pixel unit PXU2 may include a first sub-pixel unit PXU2a and a second sub-pixel unit PXU2b. First sub-pixel units PXU2a and second sub-pixel units PXU2b may be arranged alternately in the first direction DR1 and the second direction DR2.

The first sub-pixel unit PXU2a may include the (2-3)-th color pixel PX23 and the (2-2)-th color pixel PX22. The second sub-pixel unit PXU2b may include the (2-1)-th color pixel PX21 and the (2-2)-th color pixel PX22.

In one or more embodiments, the arrangement rule of the plurality of first pixels PX11, PX12, and PX13 arranged in the first region A1 or the shape of the light-emitting region defined for each of the plurality of first pixels PX11, PX12, and PX13 may be different from the arrangement rule of the plurality of second pixels PX21, PX22, and PX23 arranged in the second region A2 or the shape of the light-emitting region defined for each of the plurality of second pixels PX21, PX22, and PX23.

For example, the number of plurality of second pixels PX21, PX22, and PX23 arranged on the reference area in the second region A2 may be greater than the number of plurality of first pixels PX11, PX12, and PX13 arranged on the reference area in the first region A1. Also, the area of the plurality of second pixels PX21, PX22, and PX23 arranged on the reference area in the second region A2 may be greater than the area of the plurality of first pixels PX11, PX12, and PX13 arranged on the reference area in the first region A1.

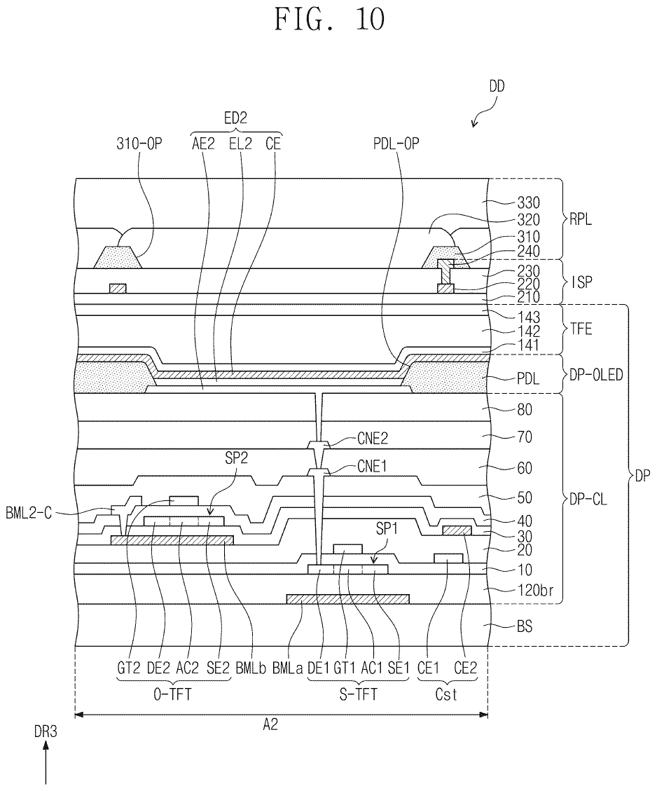

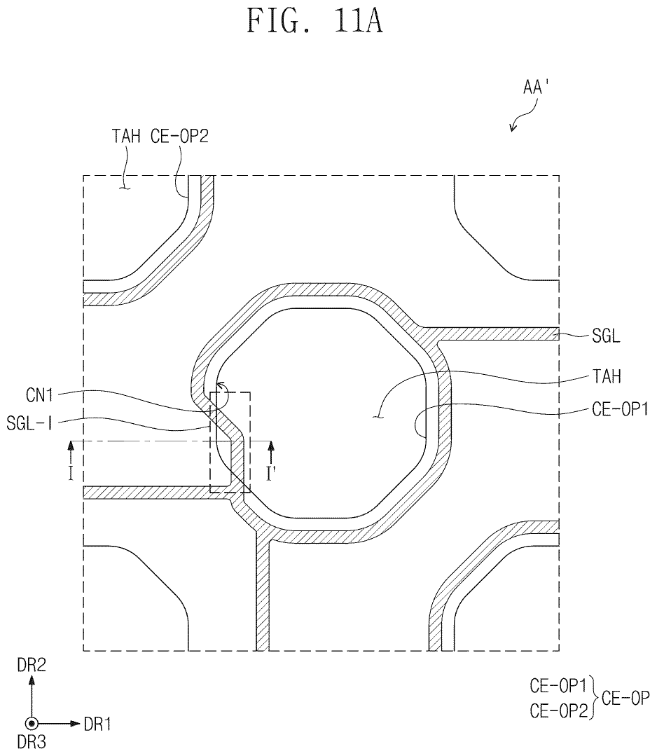

FIG. 10 is a cross-sectional view of a display module according to one or more embodiments of the present disclosure. FIG. 10 shows a cross-sectional view of a region including a pixel included in the second region A2 shown in FIG. 9B.

The display panel DP, the sensor layer ISP, and the anti-reflection layer RPL that constitute the display module DM may be stacked in the third direction DR3. The display panel DP may include a substrate BS, a circuit element layer DP-CL, a display element layer DP-OLED, and a thin film encapsulation layer TFE.

The substrate BS may provide a base surface on which the circuit element layer DP-CL is located. The substrate BS may be a rigid substrate or a flexible substrate capable of bending, folding, and rolling. The substrate BS may be a glass substrate, a metal substrate, or a polymer substrate. However, the present disclosure is not limited thereto, and the substrate BS may include an inorganic layer, an organic layer, or a composite material layer.

The circuit element layer DP-CL may be located on the substrate BS. The circuit element layer DP-CL may include a plurality of insulating layers (e.g., 120br, 10, 20, 30, 40, 50, 60, 70, 80), a semiconductor pattern, a conductive pattern, and a signal line, etc. The semiconductor pattern, the conductive pattern, and the signal line may constitute pixel drive units. An insulating layer, a semiconductor layer, and a conductive layer are formed on the substrate BS by coating, deposition, or other methods. The insulating layer, the semiconductor layer, and the conductive layer may be selectively patterned by performing photolithography processes thereon a plurality of times. As a result, the semiconductor pattern, the conductive pattern, and the signal line may be formed.

A buffer layer 120br may be located on the substrate BS (as used herein, “located on” may mean “above”). The buffer layer 120br may reduce or prevent metal atoms and impurities diffusing from the substrate BS into a first semiconductor pattern SP1. In addition, the buffer layer 120br may adjust a heat supply rate during a crystallization process for forming the first semiconductor pattern SP1, and thus, the first semiconductor pattern SP1 may be formed uniformly.

For convenience of description, FIG. 10 shows, as an example, one silicon transistor S-TFT, one oxide transistor O-TFT, and a capacitor Cst among the components of one pixel included in the second region A2.

A first rear metal layer BMLa may be located below the silicon transistor S-TFT, and a second rear metal layer BMLb may be located below the oxide transistor O-TFT. The silicon transistor S-TFT may be a transistor that includes the semiconductor layer containing the silicon described above. The oxide transistor O-TFT may be a transistor that includes the semiconductor layer containing the oxide described above. The first and second rear metal layers BMLa and BMLb may be located above the substrate BS.

The first and second rear metal layers BMLa and BMLb may reduce or prevent the effect of electric potential (due to the polarization of the substrate BS) on the components of the pixel drive unit, such as the transistors (S-TFT, O-TFT). The first and second rear metal layers BMLa and BMLb may reduce or prevent external light reaching the components of the pixel drive unit.

The first rear metal layer BMLa may be located between the substrate BS and the buffer layer 120br. In one or more embodiments of the present disclosure, an inorganic barrier layer may be further provided between the first rear metal layer BMLa and the buffer layer 120br. The first rear metal layer BMLa may be connected to an electrode or line, and may receive a constant voltage or signal therefrom. According to one or more embodiments of the present disclosure, the first rear metal layer BMLa may be a floating electrode that is isolated from other electrodes or lines.

The second rear metal layer BMLb may be located between a second insulating layer 20 and a third insulating layer 30. The second rear metal layer BMLb may be located at the same layer as a second electrode CE2 of a storage capacitor Cst. The second rear metal layer BMLb may be connected to a contact electrode BML2-C, and may receive a constant voltage or signal. The contact electrode BML2-C may be located at the same layer as a gate GT2 of the oxide transistor O-TFT.

The first rear metal layer BMLa and the second rear metal layer BMLb may each include a reflective metal. The first rear metal layer BMLa and the second rear metal layer BMLb may contain the same material or different respective materials.

The first rear metal layer BMLa and the second rear metal layer BMLb may each include silver (Ag), an alloy containing silver (Ag), molybdenum (Mo), an alloy containing molybdenum, aluminum (Al), an alloy containing aluminum, aluminum nitride (AlN), tungsten (W), tungsten nitride (WN), copper (Cu), amorphous silicon doped with p+, etc.

According to one or more embodiments of the present disclosure, the second rear metal layer BMLb may be omitted. In this case, the first rear metal layer BMLa may extend onto a lower portion of the oxide transistor O-TFT, and thus, the first rear metal layer BMLa may block light that is incident toward the lower portion of the oxide transistor O-TFT.

The first semiconductor pattern SP1 may be located on the buffer layer 120br. The first semiconductor pattern SP1 may include a silicon semiconductor. For example, the silicon semiconductor may include amorphous silicon, polycrystalline silicon, and the like. For example, the first semiconductor pattern SP1 may include low-temperature polysilicon.

In FIG. 10, a portion of the first semiconductor pattern SP1 located on the buffer layer 120br is shown. However, the present disclosure is not limited thereto, and the first semiconductor pattern SP1 may also be located in other regions. The first semiconductor pattern SP1 may be arranged in a corresponding pattern across the pixels PX.

The first semiconductor pattern SP1 may have electrical properties that vary depending on whether the first semiconductor pattern SP1 is doped or not. The first semiconductor pattern SP1 may include a first semiconductor region having high conductivity and a second semiconductor region having low conductivity. The first semiconductor region may be doped with an N-type dopant or a P-type dopant. A P-type transistor may include a doped region that is doped with the P-type dopant, and an N-type transistor may include a doped region that is doped with the N-type dopant. The second semiconductor region may be a non-doped region or a region doped at a lower concentration than the first semiconductor region.

The conductivity of the first semiconductor region may be greater than the conductivity of the second semiconductor region, and the first semiconductor region may substantially function as an electrode or signal line. The second semiconductor region may substantially correspond to an active region (or a channel) of a transistor. That is, a portion of the semiconductor pattern may be an active region of a transistor, another portion may be a source or drain of the transistor, and the other portion may be a connection electrode or a connection signal line.

A source region SE1 (or a source), an active region AC1 (or a channel), and a drain region DE1 (or a drain) of the silicon transistor S-TFT may be formed from the first semiconductor pattern SP1. The source region SE1 and the drain region DE1 may extend from the active region AC1 in opposite directions in a cross-sectional view.

A first insulating layer 10 may be located on the buffer layer 120br. The first insulating layer 10 may overlap, in common, the plurality of pixels PX, and may cover the first semiconductor pattern SP1. The first insulating layer 10 may be an inorganic layer.

A gate GT1 of the silicon transistor S-TFT may be located on the first insulating layer 10. The gate GT1 may be a portion of the metal pattern.

The second insulating layer 20 may be located on the first insulating layer 10, and may cover the gate GT1. The second insulating layer 20 may be an inorganic layer. The third insulating layer 30 may be located on the second insulating layer 20. The third insulating layer 30 may be an inorganic layer.

A first electrode CE1 of the storage capacitor Cst may be located between the first insulating layer 10 and the second insulating layer 20. A second electrode CE2 of the storage capacitor Cst may be located between the second insulating layer 20 and the third insulating layer 30.

A second semiconductor pattern SP2 may be located on the third insulating layer 30. The second semiconductor pattern SP2 may include an oxide semiconductor. The oxide semiconductor may include a plurality of regions that are classified according to whether a transparent conductive oxide has been reduced. A region in which the transparent conductive oxide has been reduced (hereinafter referred to as a reduced region) has higher conductivity than a region in which the transparent conductive oxide has not been reduced (hereinafter referred to as a non-reduced region).

The reduced region substantially serves as a source/drain of a transistor or a signal line. The non-reduced region may substantially correspond to a semiconductor region (or an active region or channel) of a transistor. That is, a portion of the second semiconductor pattern SP2 may be a semiconductor region of a transistor, another portion may be a source region/drain region of the transistor, and the other portion may be a signal transmission region.

A source region SE2, an active region AC2, and a drain region DE2 of the oxide transistor O-TFT may be formed from the second semiconductor pattern SP2. The source region SE2 and the drain region DE2 may extend from the active region AC2 in opposite directions in a cross-sectional view.

A fourth insulating layer 40 may be located on the third insulating layer 30. The fourth insulating layer 40 may overlap, in common, the plurality of pixels PX, and may cover the second semiconductor pattern SP2. The fourth insulating layer 40 may be an inorganic layer.

The gate GT2 of the oxide transistor O-TFT may be located on the fourth insulating layer 40. The gate GT2 may be a portion of a metal pattern. The gate GT2 may overlap the active region AC2. A fifth insulating layer 50 may be located on the fourth insulating layer 40, and may cover the gate GT2. The fifth insulating layer 50 may be an inorganic layer and/or an organic layer, and may have a single-layer structure or a multi-layer structure.

The first connection electrode CNE1 may be located on the fifth insulating layer 50. The first connection electrode CNE1 may be connected to the drain region DE1 of the silicon transistor S-TFT via a contact hole that passes through the first to fifth insulating layers 10, 20, 30, 40, and 50.

The sixth insulating layer 60 may be located on the fifth insulating layer 50. A second connection electrode CNE2 may be located on the sixth insulating layer 60. The second connection electrode CNE2 may be connected to the first connection electrode CNE1 via a contact hole that passes through the sixth insulating layer 60.

A seventh insulating layer 70 may be located on the sixth insulating layer 60, and may cover the second connection electrode CNE2. An eighth insulating layer 80 may be located on the seventh insulating layer 70. The sixth insulating layer 60, the seventh insulating layer 70, and the eighth insulating layer 80 may each be an organic layer.

The display element layer DP-OLED may be located on the circuit element layer DP-CL. The display element layer DP-OLED may include a light-emitting element. For example, the light-emitting element may include an organic light-emitting material, an inorganic light-emitting material, an organic-inorganic light-emitting material, a quantum dot, a quantum rod, a micro-LED, or a nano-LED.

A second light-emitting element ED2 may include a second pixel electrode AE2, a second light-emitting layer EL2, and a common electrode CE. The common electrode CE may have an integrated shape, and may be shared by the plurality of second pixels PX21, PX22, and PX23 (FIG. 9B) described above. That is, the common electrode CE may be shared by the pixels PX that are arranged in the second region A2.

The second pixel electrode AE2 may be located on the eighth insulating layer 80. The second pixel electrode AE2 may be a (semi-) transmissive electrode or a reflective electrode.

The reflective electrode may be made of Ag, Mg, Al, Pt, Pd, Au, Ni, Nd, Ir, Cr, or a compound thereof. A transparent or translucent electrode may be made of at least one of indium tin oxide (ITO), indium zinc oxide (IZO), indium gallium zinc oxide (IGZO), zinc oxide (ZnO), indium oxide (In₂O₃), or aluminum-doped zinc oxide (AZO). For example, the first pixel electrode AE1, the second pixel electrode AE2, and the third pixel electrode AE3 may be provided with ITO/Ag/ITO, respectively. The pixel-defining layer PDL may be located on the eighth insulating layer 80. The pixel-defining layer PDL may have light-absorbing characteristics. For example, the pixel-defining layer PDL may have a black color.

The pixel-defining layer PDL may be located in the second region A2. The pixel-defining layer PDL may cover the edge of the second pixel electrode AE2. An opening PDL-OP, through which a portion of the second pixel electrode AE2 is exposed, may be defined in the pixel-defining layer PDL.

The second light-emitting layer EL2 may be located on the second pixel electrode AE2. In one or more embodiments, the second light-emitting layer EL2 may emit light of at least one of blue, red, or green.

The common electrode CE may be located on the pixel-defining layer PDL and the second light-emitting layer EL2.

The common electrode CE may be a light-transmitting electrode. In one or more embodiments, the common electrode CE may be a transparent or semi-transparent electrode, and may include a metal thin film having a low work function, which contains Li, Ca, LiF/Ca, LiF/Al, Al, Ag, Mg, and a compound thereof. In addition, a transparent conductive oxide (TCO) film made of ITO, IZO, ZnO, or In₂O₃ may be located on the metal film.

In one or more embodiments, a hole control layer may be located between the second pixel electrode AE2 and the second light-emitting layer EL2. The hole control layer includes a hole transport layer, and may further include a hole injection layer. An electron control layer may be located between the second light-emitting layer EL2 and the common electrode CE. The electron control layer may include an electron transport layer, and may further include an electron injection layer.

The thin film encapsulation layer TFE may be located on the display element layer DP-OLED. The thin film encapsulation layer TFE may include an inorganic layer 141, an organic layer 142, and an inorganic layer 143, which are stacked in this order, but the layers constituting the thin film encapsulation layer TFE are not limited thereto. The inorganic layers 141 and 143 may protect the display element layer DP-OLED from moisture and oxygen, and the organic layer 142 may protect the display element layer DP-OLED from foreign substances, such as dust particles, and may provide a planarized upper surface.

The sensor layer ISP may be located on the display panel DP. The sensor layer ISP may sense an external input applied from an external source. The external input may be a user input. The user input may include various types of external inputs, such as parts of the user's body, light, heat, a pen, and pressure.

The sensor layer ISP may be formed on the display panel DP by successive processes. The sensor layer ISP may be located on the display panel DP. The sensor layer ISP may be referred to as a sensor, an input-sensing layer, or an input-sensing panel. The sensor layer ISP may be located directly on the display panel DP. For example, no additional adhesive material may be located between the sensor layer ISP and the display panel DP. However, the present disclosure is not limited thereto, and the sensor layer ISP may be bonded to the display panel DP by an adhesive member. The adhesive member may include a general adhesive or bonding agent.

The sensor layer ISP may include a sensor base layer 210, a first sensor conductive layer 220, a sensor insulating layer 230, and a second sensor conductive layer 240. The sensor base layer 210 may be located directly on the display panel DP. The sensor base layer 210 may be an inorganic layer or an organic layer. The sensor base layer 210 may have a single-layer structure or a multi-layer structure in which layers are stacked in the third direction DR3.

The first sensor conductive layer 220 and the second sensor conductive layer 240 may be located above the sensor base layer 210. The sensor insulating layer 230 may be located between the first sensor conductive layer 220 and the second sensor conductive layer 240. The sensor insulating layer 230 may include an inorganic layer or an organic layer. The first sensor conductive layer 220 and the second sensor conductive layer 240 may constitute a sensing electrode. Sensor electrodes may include the sensing electrodes (TE1, TE2 of FIG. 8) or drive electrodes. Also, each of the sensor electrodes may have a mesh shape, and the conductive pattern constituting the first sensor conductive layer 220 and the conductive pattern constituting the second sensor conductive layer 240 shown in FIG. 10 may also be a portion of the mesh shape. Also, the first sensor conductive layer 220 and the second sensor conductive layer 240 may each include a transparent electrode. Also, the sensor electrode may be constituted by the first sensor conductive layer 220, the second sensor conductive layer 240, and a third conductive layer that is located in a layer separate therefrom. The first sensor conductive layer 220 and the second sensor conductive layer 240 may be designed in various embodiments as long as these conductive layers may form a sensing pattern and sense an external input, and the present disclosure is not limited to any one embodiment. In one or more embodiments, the sensor layer ISP may further include a cover layer located on the second sensor conductive layer 240. The cover layer may include an inorganic layer or an organic layer.

The anti-reflection layer RPL may be located on the sensor layer ISP. The anti-reflection layer RPL may include a black matrix 310, a plurality of color filters 320, and a planarization layer 330.

The black matrix 310 may have a black color. The black matrix 310 may cover the second sensor conductive layer 240 of the sensor layer ISP. The black matrix 310 may reduce or prevent reflection of external light by the second sensor conductive layer 240.

A plurality of split openings 310-OP may be defined in the black matrix 310. A split opening 310-OP may overlap the second pixel electrode AE2. The area of the split openings 310-OP may be greater than the area of the openings PDL-OP of the pixel-defining layer PDL.

The color filter 320 may overlap the second pixel electrode AE2, and may be located above the second light-emitting element ED2. The color filter 320 may be located in the split opening 310-OP defined in the black matrix 310, and may cover the split opening 310-OP. The color filter 320 may be in contact with the black matrix 310.

The planarization layer 330 may be located on the color filter 320 and the black matrix 310, and may planarize the upper surface of the anti-reflection layer RPL. The planarization layer 330 may include an organic material. In one or more embodiments, the planarization layer 330 may be omitted.

The anti-reflection layer RPL may be located directly on the sensor layer ISP. The anti-reflection layer RPL may reduce the reflectance of external light that is incident from the outside of the display module DM. The anti-reflection layer RPL may be formed on the sensor layer ISP by successive processes.

The present disclosure is not limited to the configuration described above, and the anti-reflection layer RPL according to one or more embodiments of the present disclosure may include a phase retarder and a polarizer so as to reduce the reflectance of external light. The phase retarder and the polarizer may be implemented as a single polarization film. The anti-reflection layer RPL may further include a protective film that is provided on the upper or lower side of the polarization film.

In one or more embodiments of the present disclosure, the positions of the sensor layer ISP and the anti-reflection layer RPL may be reversed from each other. For example, the anti-reflection layer RPL may be located between the display panel DP and the sensor layer ISP.

In one or more embodiments of the present disclosure, the display module DM may further include an optical layer located on the anti-reflection layer RPL. The optical layer may be formed on the anti-reflection layer RPL by successive processes.

The optical layer may enhance the front luminance of the display module DM by controlling the direction of light incident from the display panel DP. For example, the optical layer may include an organic insulating layer, in which openings are defined respectively corresponding to light-emitting regions of pixels included in the display panel DP, and a high-refractive index layer, which covers the organic insulating layer and fills the openings. The high-refractive index layer may have a higher refractive index than the organic insulating layer.

FIGS. 11A and 11B are plan views each showing a portion of a display module according to one or more embodiments. FIGS. 11A and 11B are enlarged views each showing a portion of the first region A1. FIG. 11A shows a schematic plan view of region AA′ shown in FIG. 9A, focusing on the shapes of the transmissive portion TAH and the signal lines SGL adjacent thereto. FIG. 11B shows a schematic plan view of region AA′ shown in FIG. 9A, focusing on the shapes of the transmissive portion TAH and the conductive patterns of the sensor layer ISP (FIG. 8) adjacent thereto.

Referring to FIG. 11A, a portion of the signal line SGL is located around the transmissive portion TAH. The transmissive portion TAH may be defined by the electrode opening CE-OP. A portion of the signal line SGL may be positioned so as to follow a portion of the edge of the electrode opening CE-OP. The signal line SGL may include at least some of the scan lines SCL, the data lines DL, the power line PL, the light-emitting control lines EL, and the control signal line CSL described above with reference to FIG. 7.

In one or more embodiments, a portion of the signal line SGL overlaps the transmissive portion TAH. The signal line SGL includes an inner signal section SGL-I located inside the transmissive portion TAH. The inner signal section SGL-I may be located inside the transmissive portion TAH, and the remaining portion other than the inner signal section SGL-I may not overlap the transmissive portion TAH. The plurality of electrode openings CE-OP, each defining the transmissive portion TAH, may include a first electrode opening CE-OP1 and a second electrode opening CE-OP2 that are adjacent to each other in a plan view. The inner signal section SGL-I may be located inside the transmissive portion TAH that is defined by the first electrode opening CE-OP1.

Referring to FIGS. 8 and 11B together, the sensor layer ISP includes a conductive pattern including the sensing electrodes (TE1, TE2), and the conductive pattern includes the sensing pattern SSP. The sensing pattern SSP may be a component that substantially senses an external input applied from an external source. The external input may include various types of external inputs, such as parts of the user's body, light, heat, a pen, and pressure.

The conductive pattern includes a dummy pattern DMP adjacent to the sensing pattern SSP. The dummy pattern DMP may be a conductive pattern that is separated from the sensing pattern SSP, and to which no electrical signal is applied. The dummy pattern DMP may be a floating electrode that is isolated from the sensing pattern SSP. A cut portion CUT may be provided between, or defined by, the dummy pattern DMP and the sensing pattern SSP, and thus, the dummy pattern DMP may float. FIG. 11B shows an example in which a first dummy pattern DMP1 and a second dummy pattern DMP2 are separated from each other by the cut portion CUT provided therebetween, but the present disclosure is not limited thereto. The dummy pattern DMP may be provided as a single dummy pattern, or may include three or more dummy patterns.

The sensing pattern SSP may include a target-sensing pattern SSP-T that is adjacent to the dummy pattern DMP, and that is partially located between the first electrode opening CE-OP1 and the second electrode opening CE-OP2. The cut portion CUT may be provided between the target-sensing pattern SSP-T and the dummy pattern DMP. The target-sensing pattern SSP-T may include a connecting section SSP-C that is located between the first electrode opening CE-OP1 and the second electrode opening CE-OP2. Because the target-sensing pattern SSP-T adjacent to the dummy pattern DMP includes the connecting section SSP-C provided between the adjacent openings (CE-OP1, CE-OP2), even when the conductive pattern of the sensor layer ISP includes the dummy pattern DMP, the connection between the adjacent sensing patterns may be maintained without being broken.

Each of the sensing pattern SSP and dummy pattern DMP may include a mesh line. The sensing pattern SSP may include a first mesh line ML1, and the dummy pattern DMP may include a second mesh line ML2. FIG. 11B shows an example in which the line width of the first mesh line ML1 of the sensing pattern SSP is substantially the same as that of the second mesh line ML2 of the dummy pattern DMP, but the present disclosure is not limited thereto. The line width of the first mesh line ML1 may be different from that of the second mesh line ML2. The line width of the second mesh line ML2 may be less than the line width of the first mesh line ML1. The line width of the second mesh line ML2 may be less than or equal to the line width of the first mesh line ML1.

Referring to FIGS. 11A and 11B together, the dummy pattern DMP is located between the inner signal section SGL-I and the sensing pattern SSP in a plan view. The dummy pattern DMP is located between the inner signal section SGL-I and the target-sensing pattern SSP-T in a plan view. The inner signal section SGL-I may be located inside the transmissive portion TAH defined by the first electrode opening CE-OP1, and the dummy pattern DMP may be located outside and adjacent to the transmissive portion TAH in which the inner signal section SGL-I is provided. The inner signal section SGL-I may be adjacent to the inside of a first edge CN1 of the first electrode opening CE-OP1 in a plan view, and the dummy pattern DMP may be adjacent to the outside of the first edge CN1 of the first electrode opening CE-OP1 in a plan view. Accordingly, the first edge CN1 may be located between the dummy pattern DMP and the inner signal section SGL-I.

FIG. 12 is a cross-sectional view of a display module according to one or more embodiments of the present disclosure. FIG. 12 shows a cross-sectional view of a region taken along the line I-I′ shown in FIGS. 11A and 11B.

Referring to FIGS. 11A, 11B, and 12 together, in the first region A1 (FIG. 9A), the display panel DP may include the substrate BS, the circuit element layer DP-CL, the display element layer DP-OLED, and the thin film encapsulation layer TFE, which are stacked in this order in the third direction DR3. The sensor layer ISP and the anti-reflection layer RPL may be stacked on the display panel DP.

In the first region A1, a region overlapping the electrode opening CE-OP may be defined as a transmissive region TP, and the remaining region may be defined as an element region EP. Each of the plurality of first pixels PX11, PX12, and PX13 (FIG. 9A) may be located in the element region EP, and each of the plurality of first pixels PX11, PX12, and PX13 (FIG. 9A) may be spaced apart from the transmissive region TP. The transmissive region TP may be a region in which the common electrode CE, a rear metal layer BML, the plurality of insulating layers (e.g., 120br, 10, 20, 30, 40, 50, 60, 70, 80), the pixel-defining layer PDL, the black matrix 310, and the color filter 320 are at least partially removed, and may thus have higher light transmittance than the element region EP.

The substrate BS may provide a base surface on which the circuit element layer DP-CL is located. The circuit element layer DP-CL may be located on the substrate BS. The circuit element layer DP-CL may include the plurality of insulating layers (e.g., 120br, 10, 20, 30, 40, 50, 60, 70, 80), the semiconductor pattern, the conductive pattern, and the signal line, etc.

The buffer layer 120br may be located on the substrate BS. The rear metal layer BML may be located between the substrate BS and the buffer layer 120br. The rear metal layer BML may overlap the first region A1, and may not be provided in the second region A2. The rear metal layer BML may be located in the element region EP. The rear metal layer BML may have a light-blocking opening BM-OP that overlaps the transmissive region TP. The rear metal layer BML may be a pattern that functions as a mask when forming the electrode opening CE-OP in the common electrode CE. For example, light emitted from the rear surface of the substrate BS toward the common electrode CE may pass through the light-blocking opening BM-OP of the rear metal layer BML, and may reach a portion of the common electrode CE. That is, a portion of the common electrode CE may be removed by the light that passes through the light-blocking opening BM-OP of the rear metal layer BML. The light may be a laser beam. The rear metal layer BML may be connected to an electrode or line, and may receive a constant voltage or signal therefrom. The rear metal layer BML may be a floating electrode that is isolated from other electrodes or lines.

The rear metal layer BML may include silver (Ag), an alloy containing silver (Ag), molybdenum (Mo), an alloy containing molybdenum, aluminum (Al), an alloy containing aluminum, aluminum nitride (AlN), tungsten (W), tungsten nitride (WN), copper (Cu), amorphous silicon doped with p+, etc. The rear metal layer BML may include the same material as, or a different material from, each of the first and second rear metal layers BMLa and BMLb (FIG. 10) described above.

The circuit element layer DP-CL may include the plurality of insulating layers (10, 20, 30, 40, 50, 60, 70, 80) located on the buffer layer 120br. The circuit element layer DP-CL may include a plurality of inorganic insulating layers located on the rear metal layer BML. In one or more embodiments, at least some of the first insulating layer 10 to the fifth insulating layer 50, which are sequentially stacked on the buffer layer 120br, may be inorganic insulating layers. For example, the first insulating layer 10 to the fifth insulating layer 50 may all be inorganic insulating layers. The circuit element layer DP-CL may include a plurality of organic insulating layers located on the plurality of inorganic insulating layers. For example, at least one of the sixth to eighth insulating layers 60, 70, or 80 may be an organic insulating layer.

In one or more embodiments, the circuit element layer DP-CL may include a transistor electrically connected to the first light-emitting element ED1, and the description of the silicon transistor S-TFT or the oxide transistor O-TFT in FIG. 10 may apply to the transistor. The transistor electrically connected to the first light-emitting element ED1 may be located in the second region A2 rather than the first region A1, and thus, the transmittance of the first region A1 may be higher than that of the second region A2.

The circuit element layer DP-CL includes the inner signal section SGL-I located in the transmissive region TP. The inner signal section SGL-I is located inside the transmissive region TP, which is defined by the electrode opening CE-OP. The inner signal section SGL-I may correspond to a portion of the signal line SGL located around the transmissive region TP, and the remaining portion of the signal line SGL other than the inner signal section SGL-I may be located in the element region EP rather than in the transmissive region TP.

The inner signal section SGL-I may be located on the upper portion of one of the plurality of insulating layers (10, 20, 30, 40, 50, 60, 70, or 80) located on the buffer layer 120br. The inner signal section SGL-I may be located on the upper portion of one of the plurality of inorganic insulating layers. For example, the first insulating layer 10 to the fifth insulating layer 50 may be inorganic insulating layers, and the inner signal section SGL-I may be located on the upper portion of each of the fourth insulating layer 40 and the fifth insulating layer 50.

The first light-emitting element ED1 may include a first pixel electrode AE1, a first light-emitting layer EL1, and a common electrode CE. The common electrode CE may have an integrated shape, and may be shared by the plurality of second pixels PX11, PX12, and PX13 (FIG. 9A). That is, the common electrode CE may be shared by the pixels PX that are arranged in the first region A1 and the second region A2.

The electrode opening CE-OP overlapping the transmissive region TP is defined in the common electrode CE. As shown in FIG. 12, the electrode opening CE-OP may be aligned with the light-blocking opening BM-OP of the rear metal layer BML. However, the present disclosure is not limited thereto, and the width of the light-blocking opening BM-OP may be greater than or less than the width of the electrode opening CE-OP. The inner signal section SGL-I may be located in the transmissive region TP defined by the light-blocking opening BM-OP, and might not overlap, or may be separated from, the common electrode CE in a plan view. That is, the inner signal section SGL-I might not be covered by the common electrode CE, but instead may be exposed.

A defining layer opening PDP-OP overlapping the transmissive region TP may be defined in the pixel-defining layer PDL. As shown in FIG. 12, the defining layer opening PDP-OP may have a greater width than the electrode opening CE-OP and the light-blocking opening BM-OP, and thus, a portion of the defining layer opening PDP-OP may be provided in the element region EP. However, the present disclosure is not limited thereto, and the defining layer opening PDP-OP may be aligned with the electrode opening CE-OP.

The sensor layer ISP may be located on the display panel DP. The sensor layer ISP may include the sensor base layer 210, the first sensor conductive layer 220, the sensor insulating layer 230, and the second sensor conductive layer 240. The sensor base layer 210 may be an inorganic layer or an organic layer. The sensor insulating layer 230 may include an inorganic layer or an organic layer. The first sensor conductive layer 220 and the second sensor conductive layer 240 may constitute a sensing electrode. The first sensor conductive layer 220 and the second sensor conductive layer 240 may constitute the sensing pattern SSP and the dummy pattern DMP.

The sensor layer ISP includes the sensing pattern SSP and the dummy pattern DMP adjacent to the sensing pattern SSP. The dummy pattern DMP may be a conductive pattern that is separated from the sensing pattern SSP and to which no electrical signal is applied. The dummy pattern DMP may be a floating electrode that is isolated from the sensing pattern SSP. The cut portion CUT may be provided between the dummy pattern DMP and the sensing pattern SSP, and thus, the dummy pattern DMP may float. The dummy pattern DMP and the sensing pattern SSP are each located inside the element region EP and overlap the common electrode CE in a plan view.

The dummy pattern DMP is adjacent to the transmissive region TP, as compared to the sensing pattern SSP. The dummy pattern DMP may be located between the sensing pattern SSP and the transmissive region TP in a plan view. The dummy pattern DMP is located between the inner signal section SGL-I and the sensing pattern SSP in a plan view.

In the display device DD included in the electronic device according to one or more embodiments, the electrode opening CE-OP may be provided in the first region A1 by removing a portion of the common electrode CE, and the transmissive region TP defined by the electrode opening CE-OP may be a region from which the common electrode CE and other components are at least partially removed, and may thus have higher light transmittance than the element region EP.

As the display device DD has high resolution, a space is required to arrange the signal line SGL included in the circuit element layer DP-CL. Therefore, the signal line SGL in the first region A1 may include the inner signal section SGL-I, which is a portion thereof located inside the transmissive region TP.

When the sensor layer ISP does not include the dummy pattern DMP, unlike the display device DD according to one or more embodiments, the sensing pattern SSP is provided adjacent to the inner signal section SGL-I in a plan view, and thus, noise may be generated in the sensing pattern SSP by a signal that is applied to the inner signal section SGL-I. The inner signal section SGL-I is located in a region not covered by the common electrode CE and provided with the electrode opening CE-OP. Accordingly, the signal applied to the inner signal section SGL-I is not blocked, but instead is transmitted to the adjacent sensing pattern SSP, and the noise may be generated.

In the display device DD according to one or more embodiments, while including the inner signal section SGL-I, the sensor layer ISP includes the dummy pattern DMP adjacent to the inner signal section SGL-I in a plan view. Accordingly, even when a signal is applied to the inner signal section SGL-I not covered by the common electrode CE, no noise is transmitted to the sensing pattern SSP because the dummy pattern DMP floating from the sensing pattern SSP is located in a region adjacent to the inner signal section SGL-I. Therefore, in the display device DD according to one or more embodiments, generation of noise at the sensing electrode of the sensor layer ISP due to the signal line SGL of the circuit element layer DP-CL may be reduced or prevented, and the sensing sensitivity of the sensor layer ISP in the display device DD may be improved.

The anti-reflection layer RPL may be located on the sensor layer ISP, and the anti-reflection layer RPL may include the black matrix 310, the plurality of color filters 320, and the planarization layer 330.

The black matrix 310 may have a black color. The black matrix 310 may cover the second sensor conductive layer 240 of the sensor layer ISP. The black matrix 310 may cover upper portions of the sensing pattern SSP and the dummy pattern DMP. The plurality of split openings 310-OP may be defined in the black matrix 310. The split opening 310-OP may overlap the first pixel electrode AE1.

The color filter 320 may overlap the first pixel electrode AE1, and may be located above the first light-emitting element ED1. The color filter 320 may be located in the split opening 310-OP defined in the black matrix 310, and may cover the split opening 310-OP.

The black matrix 310 may be provided with a transmissive opening 310-OPP that overlaps the transmissive region TP. The size of the transmissive opening 310-OPP may be greater than the size of each of the electrode opening CE-OP and the light-blocking opening BM-OP. The color filter 320 may not overlap the transmissive opening 310-OPP. The color filter 320 is not located in a region provided with the transmissive opening 310-OPP, and thus, the light transmittance of the transmissive region TP may be improved.

Hereinafter, a display device according to one or more embodiments of the present disclosure is described in detail with reference to one or more embodiments and a comparative example. Also, the following is an example for assisting in understanding the present disclosure, and the scope of the present disclosure is not limited thereto.

In Table 1 below, one or more embodiments have a structure in which the dummy pattern DMP is provided in a region adjacent to the transmissive portion TAH provided with the inner signal section SGL-I as illustrated in FIGS. 11A to 12, and shows values obtained by simulating the capacitance between the sensing pattern SSP and the signal line SGL adjacent thereto. The comparative example has a structure in which no dummy pattern is provided in a region adjacent to the transmissive portion provided with the inner signal section and a portion of the sensing pattern is adjacent to the inner signal section, and shows values obtained by simulating the capacitance between the sensing pattern and the signal line adjacent thereto. The reference example has a structure in which no inner signal section is provided, and shows values obtained by simulating the capacitance between the sensing pattern and the signal line adjacent thereto.

TABLE 1

| | Reference | Comparative | |
|---|---|---|---|
| | Example | Example | Embodiment |
| Sensing pattern - | 0.88 fF | 1.12 fF | 0.79 fF |
| Signal line 1 | | | |
| Sensing pattern - | 0.33 fF | 0.80 fF | 0.58 fF |
| Signal line 2 | | | |
| Sensing pattern - | 0.72 fF | 1.11 fF | 0.94 fF |
| Signal line 3 | | | |
| Sensing pattern - | 0.19 fF | 0.41 fF | 0.25 fF |
| Signal line 4 | | | |

Comparing the reference example and the comparative example in Table 1, it can be seen that the capacitance between the sensing pattern and the signal lines has increased significantly due to the presence of the inner signal section, and that the capacitance between the sensing pattern and a correction signal line (signal line 2) has increased by up to about 142%. The comparative example includes the inner signal section not covered by the common electrode, and therefore, it is considered that noise has occurred between the inner signal section and the sensing pattern adjacent thereto.

Comparing the comparative example and the one or more embodiments in Table 1, it can be seen that the one or more embodiments are provided with the dummy pattern adjacent to the inner signal section, thereby reducing the capacitance between the sensing pattern and the signal lines. As a result of Table 1, even if the display device according to one or more embodiments includes the inner signal section, the sensor layer is provided with the dummy pattern adjacent to the inner signal section in a plan view, thereby reducing or preventing generation of noise in the conductive pattern of the sensor layer by the inner signal section. Accordingly, it may be expected that noise generation in the sensing electrode of the sensor layer may be reduced or prevented, and the sensing sensitivity of the sensor layer in the display device is improved.

As described above, the transmissive region is defined by the electrode opening of the common electrode, and the display device according to one or more embodiments includes the dummy pattern in which the sensor layer floats in the region adjacent to the inner signal section located in the transmissive region. Accordingly, even when the inner signal section not covered by the common electrode is provided, the defect in which the noise is generated in the conductive patterns of the sensor layer may be reduced, thereby improving the sensing sensitivity of the sensor layer.

In the above, description has been made with reference to embodiments of the present disclosure, but those skilled or of ordinary skill in the art may understand that various modifications and changes may be made to the present disclosure insofar as such modifications and changes do not depart from the spirit and technical scope of the present disclosure set forth in the claims to be described later. Therefore, the technical scope of the present disclosure is not to be limited to the contents stated in the detailed description of the specification, but should be determined by the claims, with functional equivalents thereof to be included therein.

What is claimed is:

1. An electronic device comprising:
an electronic module; and
an electronic panel comprising:
a first region comprising a transmissive region and an element region above the electronic module;
a second region adjacent to the first region;
a substrate;
a circuit element layer above the substrate and comprising:
signal lines comprising an inner signal section in the transmissive region; and
pixel circuits;
a display element layer comprising light-emitting elements electrically and respectively connected to the pixel circuits, the light-emitting elements comprising a pixel electrode, a light-emitting layer above the pixel electrode, and a common electrode above the light-emitting layer and defining electrode openings overlapping the transmissive region in a plan view; and
a sensor layer above the display element layer and comprising conductive patterns comprising:
sensing patterns overlapping the common electrode; and
a dummy pattern overlapping the common electrode, between the inner signal section and the sensing patterns in a plan view, and not electrically connected to the sensing patterns.

2. The electronic device of claim 1, wherein a cut portion is defined between one of the sensing patterns and the dummy pattern.

3. The electronic device of claim 1, wherein the sensing patterns and the dummy pattern comprise a mesh line.

4. The electronic device of claim 3, wherein the sensing patterns comprise a first mesh line,
wherein the dummy pattern comprises a second mesh line having a width that is less than or equal to a width of the first mesh line.

5. The electronic device of claim 1, wherein the circuit element layer further comprises a rear metal layer above the substrate and defining a light-blocking opening overlapping the transmissive region in a plan view.

6. The electronic device of claim 1, wherein the electrode openings comprise a first electrode opening with the inner signal section therein, and a second electrode opening adjacent to each other, and
wherein the dummy pattern is adjacent to a target-sensing pattern among the sensing patterns that is partially between the first electrode opening and the second electrode opening.

7. The electronic device of claim 6, wherein the target-sensing pattern comprises a connecting section between the first electrode opening and the second electrode opening.

8. The electronic device of claim 6, wherein the inner signal section is adjacent to a first edge of the first electrode opening in a plan view,
wherein the dummy pattern is adjacent to the first edge of the first electrode opening in a plan view, and
wherein the first edge of the first electrode opening is between the dummy pattern and the inner signal section in a plan view.

9. The electronic device of claim 1, wherein the display element layer further comprises a pixel-defining layer above the circuit element layer and configured to absorb light.

10. The electronic device of claim 1, wherein the electronic panel further comprises a thin film encapsulation layer above the display element layer and covering the light-emitting elements, and
wherein the sensor layer is directly on the thin film encapsulation layer.

11. The electronic device of claim 1, wherein the circuit element layer further comprises inorganic insulating layers above the substrate, and
wherein the inner signal section is above one of the inorganic insulating layers.

12. The electronic device of claim 11, wherein the circuit element layer further comprises organic insulating layers above the inorganic insulating layers.

13. The electronic device of claim 1, wherein the sensor layer comprises:
a sensor base layer above the display element layer;
a first sensor conductive layer above the sensor base layer;
a sensor insulating layer above the first sensor conductive layer; and
a second sensor conductive layer above the sensor insulating layer.

14. The electronic device of claim 1, wherein the electronic panel further comprises an anti-reflection layer above the sensor layer and comprising:
a black matrix defining split openings respectively overlapping the light-emitting elements; and
color filters respectively corresponding to the split openings.

15. The electronic device of claim 14, wherein the black matrix defines a transmissive opening at least partially overlapping the transmissive region, and
wherein the color filters are spaced from the transmissive opening.

16. An electronic device comprising:
an electronic module; and
an electronic panel comprising:
a first region above the electronic panel and comprising a transmissive region and an element region;
a second region adjacent to the first region;
a substrate;
a circuit element layer above the substrate and comprising:
signal lines comprising an inner signal section in the transmissive region; and
pixel circuits above the substrate;
a display element layer comprising light-emitting elements electrically and respectively connected to the pixel circuits and comprising a pixel electrode, a light-emitting layer above the pixel electrode, and a common electrode above the light-emitting layer and defining electrode openings partially overlapping the transmissive region in a plan view; and
a sensor layer above the display element layer and comprising conductive patterns comprising:
a sensing pattern overlapping the common electrode; and
a dummy pattern overlapping the common electrode, adjacent to the inner signal section in a plan view, and spaced apart from the sensing pattern with a cut portion therebetween.

17. The electronic device of claim 16, wherein the electrode openings comprise a first electrode opening in which the inner signal section is located,
wherein the inner signal section is adjacent to a first edge of the first electrode opening in a plan view,
wherein the dummy pattern is adjacent to the first edge of the first electrode opening in a plan view, and
wherein the first edge of the first electrode opening is between the dummy pattern and the inner signal section.

18. The electronic device of claim 16, wherein the circuit element layer further comprises inorganic insulating layers above the substrate, and
wherein the inner signal section is above one of the inorganic insulating layers.

19. The electronic device of claim 16, wherein the electronic panel further comprises an anti-reflection layer above the sensor layer and comprising:
a black matrix defining split openings respectively overlapping the light-emitting elements and a transmissive opening at least partially overlapping the transmissive region; and
color filters respectively corresponding to the split openings and spaced from the transmissive opening.

20. A display panel comprising:
a first region comprising a transmissive region and an element region;
a second region adjacent to the first region;
a substrate;
a circuit element layer above the substrate and comprising:
signal lines comprising an inner signal section in the transmissive region; and
pixel circuits;
a display element layer comprising light-emitting elements respectively electrically connected to the pixel circuits and comprising a pixel electrode, a light-emitting layer above the pixel electrode, and a common electrode above the light-emitting layer and defining electrode openings partially overlapping the transmissive region in a plan view; and
a sensor layer above the display element layer and comprising conductive patterns comprising:
sensing patterns overlapping the common electrode; and
a dummy pattern overlapping the common electrode, between the inner signal section and the sensing patterns in a plan view, and not electrically connected to the sensing patterns.
